(19) United States
(12) Patent Application Publication
(10) Pub. No.: US 2026/0130152 A1
(43) Pub. Date: May 7, 2026

(54) METHOD OF MANUFACTURING SEMICONDUCTOR DEVICE AND SEMICONDUCTOR DEVICE

(71) Applicant: Kioxia Corporation, Tokyo (JP)

(72) Inventor: Ryoji YAMADA, Yokkaichi (JP)

(73) Assignee: Kioxia Corporation, Tokyo (JP)

(21) Appl. No.: 19/308,528

(22) Filed: Aug. 25, 2025

(30) Foreign Application Priority Data
Nov. 1, 2024 (JP) 2024-193243
May 15, 2025 (JP) 2025-082217

(51) Int. Cl. H01L 21/78; B23K 26/364; B23K 26/53; B23K 101/40; H01L 23/00; H10B 43/10; H10B 43/27; H10B 43/35

(52) U.S. Cl. CPC H10P 54/00; B23K 26/364; B23K 26/53; B23K 2101/40; H10B 43/10; H10B 43/27; H10B 43/35; H10W 90/751

(57) ABSTRACT

Embodiments provide a method of manufacturing a semiconductor device, including forming two grooves that extend from a first surface of a semiconductor wafer along a dicing region of the semiconductor wafer and are arranged side by side, the semiconductor wafer including the first surface and a second surface opposite to the first surface. The manufacturing method includes irradiating between the two grooves from the second surface of the semiconductor wafer with a first laser beam when viewed from above to form a modified portion in the semiconductor wafer along the dicing region. The manufacturing method includes cleaving the semiconductor wafer to segment the semiconductor wafer into a plurality of semiconductor chips.

### CROSS REFERENCE TO RELATED APPLICATIONS

This application is based upon and claims the benefit of priority from the prior Japanese Patent Application No. 2024-193243, filed on Nov. 1, 2024 and the prior Japanese Patent Application No. 2025-082217, filed on May 15, 2025, the entire contents of which are incorporated herein by reference.

### FIELD

Embodiments of the present invention relate to a method of manufacturing a semiconductor device and a semiconductor device.

### BACKGROUND

In dicing using laser light, it is desirable for cracks to propagate appropriately from a modified portion (modified layer) in order to properly segment a wafer into a plurality of chips.

### BRIEF DESCRIPTION OF THE DRAWINGS

FIG. 1 is a plan view illustrating an example of a configuration of a portion of a semiconductor wafer according to a first embodiment;

FIG. 2 is a perspective view illustrating a semiconductor device according to the first embodiment;

FIG. 3 is a plan view illustrating a stacked body;

FIG. 4 is a cross sectional view illustrating an example of a memory cell having a three-dimensional structure;

FIG. 5 is a cross sectional view illustrating an example of the memory cell having a three-dimensional structure;

FIG. 6 is a plan view illustrating an example of the semiconductor device according to the first embodiment;

FIG. 7 is a cross sectional view illustrating an example of a configuration of a chip region and a dicing region;

FIG. 8A is a perspective view illustrating an example of a method of manufacturing the semiconductor device according to the first embodiment;

FIG. 8B is a perspective view illustrating an example of the method of manufacturing the semiconductor device, following FIG. 8A;

FIG. 8C is a perspective view illustrating an example of the method of manufacturing the semiconductor device, following FIG. 8B;

FIG. 8D is a perspective view illustrating an example of the method of manufacturing the semiconductor device, following FIG. 8C;

FIG. 8E is a perspective view illustrating an example of the method of manufacturing the semiconductor device, following FIG. 8D;

FIG. 8F is a perspective view illustrating an example of the method of manufacturing the semiconductor device, following FIG. 8E;

FIG. 8G is a perspective view illustrating an example of the method of manufacturing the semiconductor device, following FIG. 8F;

FIG. 8H is a perspective view illustrating an example of the method of manufacturing the semiconductor device, following FIG. 8G;

FIG. 9A is a cross sectional view illustrating an example of the method of manufacturing the semiconductor device according to the first embodiment;

FIG. 9B is a cross sectional view illustrating an example of the method of manufacturing the semiconductor device, following FIG. 9A;

FIG. 9C is a cross sectional view illustrating an example of the method of manufacturing the semiconductor device, following FIG. 9B;

FIG. 10A is a cross sectional view illustrating an example of a configuration of the semiconductor device according to the first embodiment;

FIG. 10B is a cross sectional view illustrating an example of a configuration of the semiconductor device according to the first embodiment;

FIG. 11A is a cross sectional view illustrating an example of a method of manufacturing a semiconductor device according to a comparative embodiment;

FIG. 11B is a cross sectional view illustrating an example of the method of manufacturing the semiconductor device, following FIG. 11A;

FIG. 12A is a perspective view illustrating an example of a method of manufacturing a semiconductor device according to a second embodiment;

FIG. 12B is a perspective view illustrating an example of the method of manufacturing the semiconductor device, following FIG. 12A;

FIG. 13 is a cross sectional view illustrating an example of a method of manufacturing a semiconductor device according to a third embodiment;

FIG. 14 is a cross sectional view illustrating an example of a method of manufacturing a semiconductor device according to a fourth embodiment;

FIG. 15 is a cross sectional view illustrating an example of a method of manufacturing a semiconductor device according to a fifth embodiment;

FIG. 16A is a cross sectional view illustrating an example of a method of manufacturing a semiconductor device according to a sixth embodiment;

FIG. 16B is a cross sectional view illustrating an example of the method of manufacturing the semiconductor device, following FIG. 16A;

FIG. 17A is a cross sectional view illustrating an example of a method of manufacturing a semiconductor device according to a seventh embodiment;

FIG. 17B is a cross sectional view illustrating an example of the method of manufacturing the semiconductor device, following FIG. 17A;

FIG. 18A is a cross sectional view illustrating an example of a method of manufacturing a semiconductor device according to an eighth embodiment;

FIG. 18B is a cross sectional view illustrating an example of the method of manufacturing the semiconductor device, following FIG. 18A;

FIG. 19A is a cross sectional view illustrating an example of a method of manufacturing a semiconductor device according to a ninth embodiment;

FIG. 19B is a cross sectional view illustrating an example of the method of manufacturing the semiconductor device, following FIG. 19A;

FIG. 20A is a cross sectional view illustrating an example of a method of manufacturing a semiconductor device according to a tenth embodiment;

FIG. 20B is a cross sectional view illustrating an example of the method of manufacturing the semiconductor device, following FIG. 20A;

FIG. 21A is a cross sectional view illustrating an example of a method of manufacturing a semiconductor device according to an eleventh embodiment;

FIG. 21B is a cross sectional view illustrating an example of the method of manufacturing the semiconductor device, following FIG. 21A;

FIG. 22A is a cross sectional view illustrating an example of a method of manufacturing a semiconductor device according to a twelfth embodiment;

FIG. 22B is a cross sectional view illustrating an example of the method of manufacturing the semiconductor device, following FIG. 22A;

FIG. 23A is a cross sectional view illustrating an example of a method of manufacturing a semiconductor device according to a thirteenth embodiment;

FIG. 23B is a cross sectional view illustrating an example of the method of manufacturing the semiconductor device, following FIG. 23A;

FIG. 24A is a cross sectional view illustrating an example of a method of manufacturing a semiconductor device according to a fourteenth embodiment;

FIG. 24B is a cross sectional view illustrating an example of the method of manufacturing the semiconductor device, following FIG. 24A;

FIG. 25A is a cross sectional view illustrating an example of a method of manufacturing a semiconductor device according to a fifteenth embodiment;

FIG. 25B is a cross sectional view illustrating an example of the method of manufacturing the semiconductor device, following FIG. 25A;

FIG. 26A is a cross sectional view illustrating an example of a method of manufacturing a semiconductor device according to a sixteenth embodiment;

FIG. 26B is a cross sectional view illustrating an example of the method of manufacturing the semiconductor device, following FIG. 26A;

FIG. 27A is a cross sectional view illustrating an example of a method of manufacturing a semiconductor device according to a seventeenth embodiment; and

FIG. 27B is a cross sectional view illustrating an example of the method of manufacturing the semiconductor device, following FIG. 27A.

### DETAILED DESCRIPTION

Embodiments will now be explained with reference to the accompanying drawings. The present invention is not limited to the embodiments. It should be noted that the drawings are schematic or conceptual, and the relationship between the thickness and the width in each element and the ratio among the dimensions of elements do not necessarily match the actual ones. Even if two or more drawings show the same portion, the dimensions and the ratio of the portion may differ in each drawing. In the present specification and the drawings, elements identical to those described in the foregoing drawings are denoted by like reference characters and detailed explanations thereof are omitted as appropriate.

Embodiments provide a method of manufacturing a semiconductor device, including forming two grooves that extend from a first surface of a semiconductor wafer along a dicing region of the semiconductor wafer and are arranged side by side, the semiconductor wafer including the first surface and a second surface opposite to the first surface. The manufacturing method includes irradiating between the two grooves from the second surface of the semiconductor wafer with a first laser beam when viewed from above to form a modified portion in the semiconductor wafer along the dicing region. The manufacturing method includes cleaving the semiconductor wafer to segment the semiconductor wafer into a plurality of semiconductor chips.

In the following embodiments, a semiconductor storage device including a memory cell array having a three-dimensional structure will be described as an example of a semiconductor device. However, the semiconductor device according to the embodiments is not limited thereto.

### First Embodiment

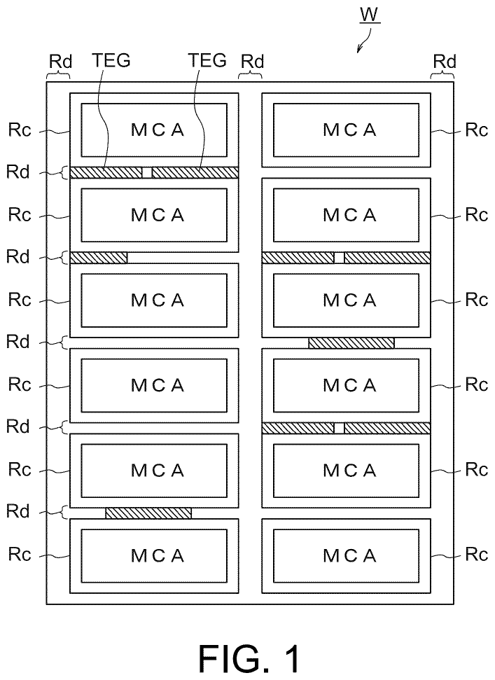

FIG. 1 is a plan view illustrating an example of a configuration of a part of a semiconductor wafer W according to a first embodiment. The semiconductor wafer W includes a front surface on which semiconductor elements are formed, and a back surface opposite to the front surface. FIG. 1 illustrates a plan view of the front surface of the semiconductor wafer W.

The semiconductor wafer W includes, on the front surface, a plurality of chip regions Rc and a plurality of dicing regions Rd. The chip regions Rc are semiconductor chip regions that are segmented into semiconductor chips, respectively, in a subsequent dicing process. The chip regions Rc are formed with chip patterns. In the present embodiment, the chip pattern includes a memory cell array MCA, for example. A control circuit is provided below the memory cell array MCA to control the memory cell array MCA, and is not illustrated in FIG. 1.

The dicing regions Rd are provided between each the plurality of chip regions Rc adjacent to each other, and are cut (removed) to segment the chip regions Rc in a subsequent dicing process. A test pattern TEG is provided in each of the dicing regions Rd.

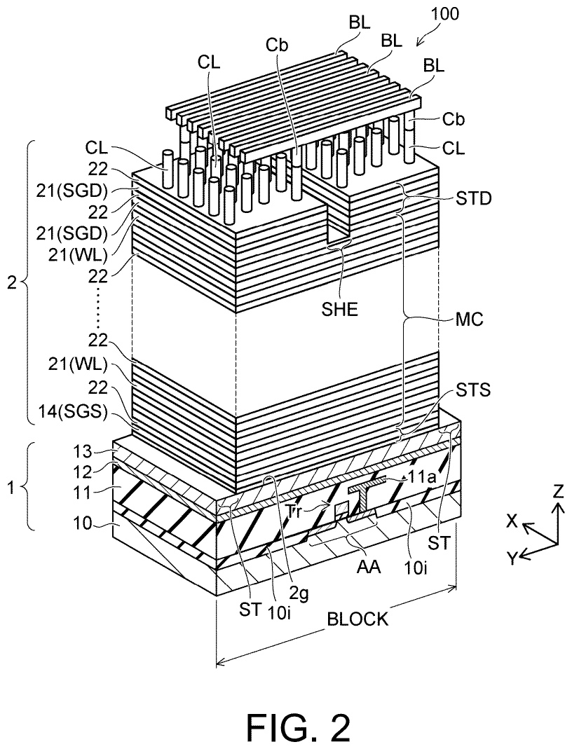

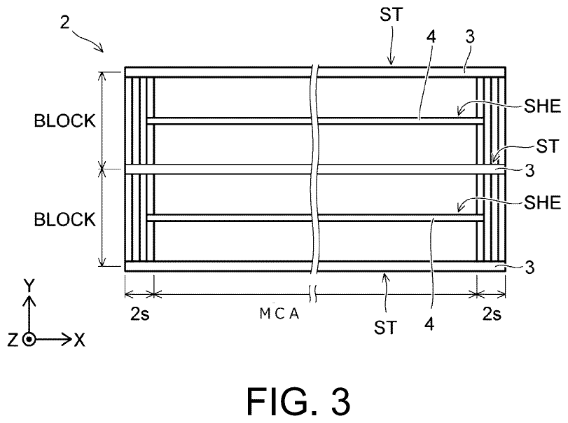

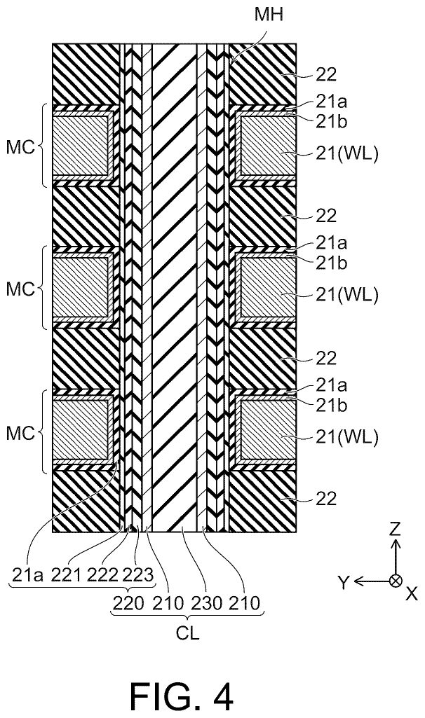

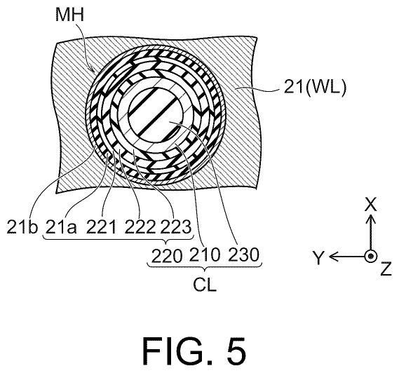

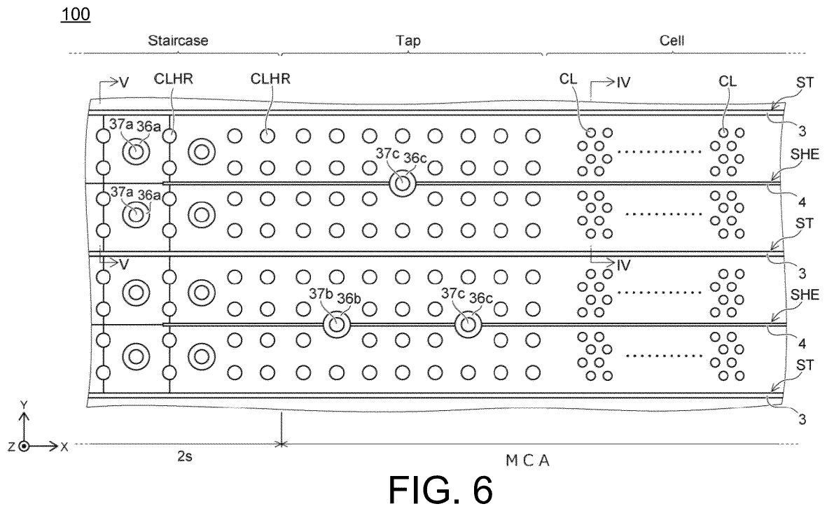

FIG. 2 is a perspective view illustrating a semiconductor device 100 according to the first embodiment. FIG. 3 is a plan view illustrating a stacked body 2. In the description, a stacking direction of the stacked body 2 is defined as a Z-axis direction. One direction orthogonal to the Z-axis direction is defined as a Y-axis direction. A direction orthogonal to each of the Z-axis direction and the Y-axis direction is defined as an X-axis direction. FIGS. 4 and 5 are cross sectional views illustrating examples of a memory cell having a three-dimensional structure, respectively. FIG. 6 is a plan view illustrating an example of the semiconductor device 100 according to the first embodiment. As illustrated in FIGS. 2 to 6, the semiconductor device 100 according to the first embodiment is a non-volatile memory including a memory cell array having a three-dimensional structure. The semiconductor device 100 is provided in a chip region Rc, but may be provided in a test pattern TEG and interpreted as a test structure.

The semiconductor device 100 includes a base portion 1, the stacked body 2, a plate-like portion 3, a plurality of columns CL, and a plurality of columns CLHR.

The base portion 1 includes a semiconductor substrate 10, an insulating film 11, a conductive film 12, and a semiconductor portion 13. The insulating film 11 is provided on the semiconductor substrate 10. The conductive film 12 is provided on the insulating film 11. The semiconductor portion 13 is provided on the conductive film 12. The semiconductor substrate 10 is, for example, a silicon substrate. A conductivity type of the semiconductor substrate 10 is, for example, a p-type. For example, an element isolation region 10i is provided in a surface region of the semiconductor substrate 10. The element isolation region 10i is, for example, an insulating region including a silicon oxide film and defines an active area AA in the surface region of the semiconductor substrate 10. The source and drain regions of a transistor Tr are provided in the active area AA. The transistor Tr constitutes a complementary metal oxide semiconductor (CMOS) circuit as a control circuit of a non-volatile memory. The insulating film 11 includes, for example, a silicon oxide film and insulates the transistor Tr. Wiring 11a is provided in the insulating film 11. The wiring 11a is electrically connected to the transistor Tr. The conductive film 12 contains a conductive metal, for example, tungsten (W). The semiconductor portion 13 contains, for example, n-type silicon. A part of the semiconductor portion 13 may contain undoped silicon.

The stacked body 2 is located above the semiconductor portion 13 in the Z-axis direction. The stacked body 2 is configured by alternately stacking a plurality of conductive layers 21 and a plurality of insulating layers 22 in the Z-axis direction. The conductive layers 21 contain a conductive metal, for example, tungsten. The insulating layers 22 contain, for example, a silicon oxide. The insulating layers 22 insulate the conductive layers 21 from each other. The number of stacked conductive layers 21 and the number of stacked insulating layers 22 are arbitrary. The insulating layers 22 may be, for example, gaps. For example, an insulating film 2g is provided between the stacked body 2 and the semiconductor portion 13. The insulating film 2g includes, for example, a silicon oxide film. The insulating film 2g may contain a high-permittivity dielectric material having a relative permittivity higher than that of a silicon oxide. The high-permittivity dielectric material may be, for example, an oxide including a hafnium oxide film.

The conductive layer 21 includes at least one source-side select gate SGS, a plurality of word lines WL, and at least one drain-side select gate SGD. The source-side select gate SGS is a gate electrode of a source-side select transistor STS. Each of the word lines WL is a gate electrode of a memory cell MC. The drain-side select gate SGD is a gate electrode of a drain-side select transistor STD. The source-side select gate SGS is provided in a lower region of the stacked body 2. The drain-side select gate SGD is provided in an upper region of the stacked body 2. The lower region indicates a region of the stacked body 2 closer to the base portion 1, and the upper region indicates a region of the stacked body 2 farther from the base portion 1. The word lines WL are provided between the source-side select gate SGS and the drain-side select gate SGD.

Out of the plurality of insulating layers 22, a thickness in the Z-axis direction of the insulating layer 22, which insulates the source-side select gate SGS from the word lines WL may be thicker than, for example, a thickness in the Z-axis direction of the insulating layer 22, which insulates the word lines WL from each other. Furthermore, a cover insulating film may be provided on the uppermost insulating layer 22 farthest from the base portion 1. The cover insulating film contains, for example, a silicon oxide.

The semiconductor device 100 includes a plurality of memory cells MC connected in series between the source-side select transistor STS and the drain-side select transistor STD. A structure in which the source-side select transistor STS, the memory cells MC, and the drain-side select transistor STD are connected in series is referred to a “memory string” or a “NAND string”. The memory string is connected to, for example, bit lines BL through contacts Cb. The bit lines BL are provided above the stacked body 2 and extend in the Y-axis direction.

A plurality of deep slits ST and a plurality of shallow slits SHE are provided in the stacked body 2 as illustrated in FIG. 3. The slits ST extend in the X-axis direction in a planar layout. The slits ST penetrate through the stacked body 2 from an upper end of the stacked body 2 to the base portion 1 at a cross section in the Z direction (stacking direction) and are provided in the stacked body 2. The plate-like portion 3 in FIG. 3 is provided in each of the slits ST. For example, an insulating film such as a silicon oxide film is used for the plate-like portion 3. The plate-like portion 3 is made of a conductive metal such as a conductive material (for example, tungsten or copper) electrically connected to the semiconductor portion 13, and is electrically insulated from the stacked body 2 by an insulating film. The slits SHE extend in the X-axis direction substantially in parallel with the slits ST in the planar layout. The slits SHE are provided from the upper end of the stacked body 2 to the middle of the stacked body 2 in the cross section in the Z direction. For example, an insulator 4 is provided in each of the slits SHE. For example, an insulating film such as a silicon oxide film is used for the insulator 4.

As illustrated in FIG. 3, the stacked body 2 includes staircase portions 2s and a memory cell array MCA. The staircase portions 2s are provided at edge portions of the stacked body 2, respectively. The memory cell array MCA is sandwiched or surrounded by the staircase portions 2s. The slit ST is provided from the staircase portion 2s at one end of the stacked body 2 to the staircase portion 2s at the other end of the stacked body 2 through the memory cell array MCA. The slit SHE is provided at least in the memory cell array MCA.

A part of the stacked body 2 sandwiched by two slits ST (plate-like portions 3) is referred to as a block BLOCK. The block constitutes, for example, a minimum unit of data erasure. The slits SHE (insulators 4) are provided in the block. The stacked body 2 between the slit ST and the slit SHE is referred to as a finger. The drain-side select gate SGD is partitioned for each finger. Accordingly, during data writing and reading, one of the fingers in a block can be brought into a selected state by the drain-side select gate SGD.

As illustrated in FIG. 6, the memory cell array MCA includes a cell region (Cell) and a tap region (Tap). The staircase portion 2s includes a staircase region (Staircase). The tap region is provided between the cell region and the staircase region, for example. Although not illustrated in FIG. 6, the tap region may be provided between the cell regions. The staircase region is a region in which a plurality of wiring 37a are provided. The tap region is a region in which wiring 37b and wiring 37c are provided. Each of the wirings 37a to 37c extends in the Z-axis direction, for example. Each of the wiring 37a is electrically connected to the conductive layer 21, for example. The wiring 37b is electrically connected to, for example, wiring 11a to supply power to the transistor Tr. The wiring 37c is electrically connected to the conductive film 12, for example. The wirings 37a to 37c are made of a low-resistance metal such as copper or tungsten.

Insulating films 36a to 36c are provided around the wirings 37a to 37c, respectively. The insulating films 36a to 36c are provided between the wirings 37a to 37c and the stacked body 2 to electrically insulate them from each other. This makes it possible to electrically connect the wirings above the stacked body 2 to the wirings below the stacked body 2 while the wirings 37a to 37c are insulated from the stacked body 2. For example, an insulating film such as a silicon oxide film is used as the insulating films 36a to 36c. In addition, the insulating film 36b and the wiring 37b form a contact C4 provided in the tap region.

The plurality of columns CL are respectively provided in memory holes MH provided in the stacked body 2. The memory holes MH penetrate the stacked body 2 from an upper end of the stacked body 2 in the stacking direction of the stacked body 2 (Z-axis direction), and extend into the stacked body 2 and the semiconductor portion 13. As illustrated in FIGS. 4 and 5, each of the plurality of columns CL includes a semiconductor body 210, a memory film 220, and a core layer 230. The semiconductor body 210 is electrically connected to the semiconductor portion 13. The memory film 220 includes a charge trapping portion between the semiconductor body 210 and the conductive layer 21. The plurality of columns CL selected one by one from each finger are commonly connected to one bit line BL through contacts Cb. Each of the columns CL is provided in, for example, a cell region (Cell) in FIG. 6.

As illustrated in FIGS. 4 and 5, the shape of each memory hole MH on an X-Y plane is, for example, circle or ellipse. A block insulating film 21a that constitutes a part of the memory film 220 may be provided between the conductive layer 21 and the insulating layer 22. The block insulating film 21a is, for example, a silicon oxide film or a metallic oxide film. One example of the metallic oxide is aluminum oxide. A barrier film 21b may be provided between the conductive layer 21 and the insulating layer 22 and between the conductive layer 21 and the memory film 220. For the barrier film 21b, for example, in a case where the conductive layer 21 is tungsten, a stacked structure film of a titanium nitride and titanium, for example, is selected. The block insulating film 21a prevents back tunneling of electric charges from the conductive layer 21 toward the memory film 220. The barrier film 21b improves adhesion between the conductive layer 21 and the block insulating film 21a.

The shape of the semiconductor body 210 is, for example, tubular. The semiconductor body 210 contains, for example, silicon. The silicon is, for example, polysilicon obtained by crystallizing amorphous silicon. The semiconductor body 210 is, for example, undoped silicon. The semiconductor body 210 may be p-type silicon. The semiconductor body 210 serves as a channel for each of the drain-side select transistor STD, the memory cells MC, and the source-side select transistor STS.

The memory film 220 is provided between an inner wall of the memory hole MH and the semiconductor body 210. The memory film 220 is, for example, a tubular shape. A plurality of memory cells MC include a storage region between the semiconductor body 210 and the conductive layers 21 as word lines WL and are stacked in the Z-axis direction. The memory film 220 includes, for example, a cover insulating film 221, a charge trapping film 222, and a tunnel insulating film 223. Each of the semiconductor body 210, the charge trapping film 222, and the tunnel insulating film 223 extends in the Z-axis direction.

The cover insulating film 221 is provided between the conductive layer 21 and the insulating layer 22 and the charge trapping film 222. The cover insulating film 221 is made of, for example, a silicon oxide. The cover insulating film 221 protects the charge trapping film 222 from being etched when a sacrificial film (not illustrated) is replaced with the conductive layer 21. The cover insulating film 221 may be removed between the conductive layer 21 and the memory film 220 in a replacing process. In this case, as illustrated in FIGS. 4 and 5, for example, the block insulating film 21a is provided between the conductive layer 21 and the charge trapping film 222. The cover insulating film 221 may not be provided in a case where the replacing process is not used to form the conductive layer 21.

The charge trapping film 222 is provided between the cover insulating film 221 and the tunnel insulating film 223. The charge trapping film 222 contains, for example, a silicon nitride and includes trap sites in the film that trap charges. A portion of the charge trapping film 222 sandwiched between the conductive layer 21 as a word line WL and the semiconductor body 210 serves as a charge trapping portion and constitutes the storage region of the memory cell MC. The threshold voltage of the memory cell MC changes depending on the presence or absence of electric charges in the charge trapping portion or the amount of electric charge trapped in the charge trapping portion. This allows the memory cell MC to retain information.

The tunnel insulating film 223 is provided between the semiconductor body 210 and the charge trapping film 222. For example, a silicon oxide or combination of a silicon oxide and a silicon nitride is used as the tunnel insulating film 223. The tunnel insulating film 223 is a potential barrier between the semiconductor body 210 and the charge trapping film 222. For example, when electrons are injected from the semiconductor body 210 into the charge trapping portion (write operation) and when holes are injected from the semiconductor body 210 into the charge trapping portion (erase operation), the electrons and holes pass (tunnel) through the potential barrier of the tunnel insulating film 223.

The core layer 230 buries the inner space of the tubular semiconductor body 210. The shape of the core layer 230 has, for example, a columnar shape. For example, an insulating film such as a silicon oxide film is used for the core layer 230.

The plurality of columns CLHR are respectively provided in holes provided in the stacked body 2. The holes are provided into the stacked body 2 and the semiconductor portion 13 by passing through the stacked body 2 in the Z-axis direction from the upper end of the stacked body 2. For example, an insulator such as a silicon oxide film is used for the column CLHR. Each of the columns CLHR may have the same structure as each of the columns CL. Each of the columns CLHR is provided in the staircase region (Staircase) and the tap region (Tap), for example. Each of the columns CLHR functions as a support member for holding a void formed in the staircase region and the tap region when the sacrifice film is replaced with the conductive layers 21 (replacing process).

As illustrated in FIG. 2, the semiconductor device 100 further includes a semiconductor portion 14. The semiconductor portion 14 is positioned between the stacked body 2 and the semiconductor portion 13. The semiconductor portion 14 is provided between an insulating layer 22 closest to the semiconductor portion 13 among the insulating layers 22 and the insulating film 2g. The semiconductor portion 14 has, for example, an n-type conductivity. The semiconductor portion 14 functions as, for example, the source-side select gate SGS.

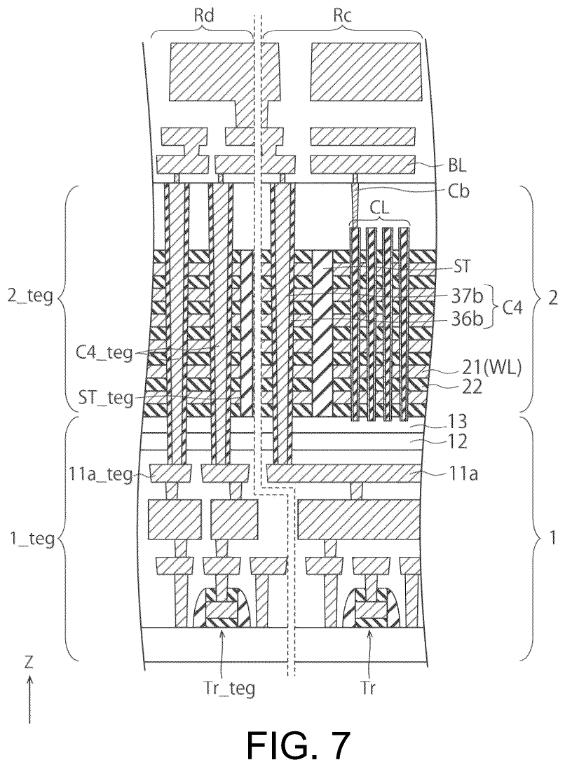

FIG. 7 is a cross sectional view illustrating an example of a configuration of the chip region Rc and the dicing region Rd. For convenience, the column CL, the slit ST, and the contact C4 in the memory cell array MCA are arranged side by side in the chip region Rc in FIG. 7. A slit ST_teg and a contact C4_teg in the test pattern TEG are arranged side by side in the dicing region Rd in FIG. 7.

In the chip region Rc, the transistor Tr in a CMOS circuit is provided in the base portion 1. A multilayer wiring structure including the wiring 11a is provided on the transistor Tr. The conductive film 12 and the semiconductor portion 13 are provided on the wiring 11a.

The stacked body 2 is provided above the base portion 1 as described above. In the stacked body 2 in the chip region Rc, the column CL described above extends from above the stacked body 2 to the semiconductor portion 13 in the stacking direction (Z direction) of the conductive layer 21 and the insulating layer 22. The semiconductor bodies 210 (FIG. 4) of the plurality of columns CL in the same finger are electrically connected to different bit lines BL through the contacts Cb, respectively. This allows data in the finger selected by the drain-side select gate SGD to be read out via each of the bit lines BL when one word line WL is selected. Alternatively, data is written to the memory cell MC in the selected finger via each of the bit lines BL.

The slits ST penetrate the stacked body 2 from the upper end of the stacked body 2 to the base portion 1 and are provided in the stacked body 2.

The contact C4 extends in the stacked body 2 in the stacking direction of the stacked body 2, and penetrates the stacked body 2, the semiconductor portion 13, and the conductive film 12 from above the stacked body 2 to the wiring 11a of the base portion 1. The contact C4 electrically connects power supply wiring above the stacked body 2 to the wiring 11a, and is electrically connected to the CMOS circuit including the transistor Tr via the wiring 11a. For example, the contact C4 may be a power contact provided to supply the power to the CMOS circuit. As described above, the contact C4 is configured by the wiring 37b and the insulating film 36b. The insulating film 36b is provided between the conductive layer 21 and the wiring 37b in the stacked body 2, and covers around the wiring 37b. Since the insulating film 36b is covered around the wiring 37b, the wiring and the like above the stacked body 2 can be electrically connected to the wiring 11a and the like below the stacked body 2 in a state where the wiring 37b is insulated from the stacked body 2.

A transistor Tr_teg in the test pattern TEG is provided in a base portion 1_teg in the dicing region Rd. The transistor Tr_teg forms a part of a CMOS circuit of the test pattern TEG. A multilayer wiring structure including a wiring 11a_teg is provided on the transistor Tr_teg. The conductive film 12 and the semiconductor portion 13 are provided on the wiring 11a_teg.

A stacked body 2_teg is provided above the base portion 1_teg. The stacked body 2_teg has the same configuration as the stacked body 2. In other words, the stacked body 2_teg is provided above the transistor Tr_teg, and has a configuration in which a plurality of insulating layers 22 and a plurality of conductive layers 21 are alternately stacked. A slit ST_teg and a contact C4_teg are provided on the stacked body 2_teg.

The slit ST_teg has the same configuration as the slit ST. In other words, the slit ST_teg penetrates the stacked body 2_teg from an upper end of the stacked body 2_teg to the base portion 1_teg in the dicing region Rd, and is provided in the stacked body 2_teg. An insulating film such as a silicon oxide film is buried in the slit ST_teg.

The contact C4_teg extends in the stacking direction of the stacked body 2_teg in the dicing region Rd, and penetrates the stacked body 2_teg, the semiconductor portion 13, and the conductive film 12 from above the stacked body 2_teg to the wiring 11a_teg of the base portion 1_teg. For example, the contact C4_teg is provided to electrically connect power supply wiring above the stacked body 2_teg to the wiring 11a_teg, and to supply the power to the CMOS circuit including the transistor Tr_teg. The contact C4_teg has the same configuration as the contact C4. In other words, the contact C4_teg is configured by the wiring 37b and the insulating film 36b that covers around the wiring 37b. This makes it possible to electrically connect the wiring above the stacked body 2_teg to the wiring 11a_teg below the stacked body 2_teg in a state where the wiring 37b is insulated from the stacked body 2_teg.

According to the present embodiment, as illustrated in FIG. 7, the stacked body 2_teg is also provided in the test pattern TEG in the dicing region Rd. The stacked body 2_teg has the same configuration as the stacked body 2 in the chip region Rc, and is provided around the contact C4_teg having the same configuration as the contact C4. Therefore, the transistor Tr_teg of the test pattern TEG can be tested under almost the same environment as the transistor Tr in the chip region Rc. Therefore, characteristics of the transistor Tr below the stacked body 2 (memory cell array MCA) can be detected by measurement of the transistor Tr_teg. As a result, the influence of the stacked body 2 on the transistor Tr can be detected.

Next, a method of segmenting the semiconductor wafer W into a plurality of chips will be described.

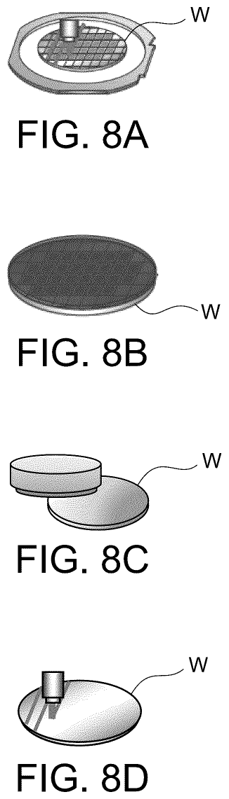

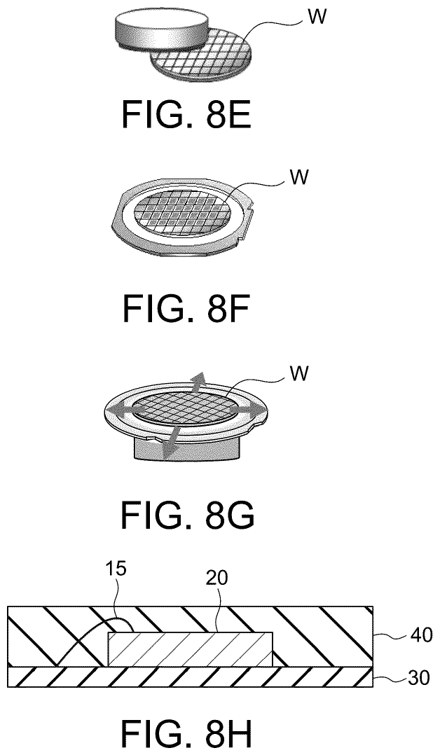

FIGS. 8A to 8H are perspective views illustrating an example of a method of manufacturing the semiconductor device 100 according to the first embodiment. The semiconductor device 100 according to the first embodiment includes, for example, semiconductor chips CH which are subjected to segmenting.

The semiconductor wafer W includes a surface F1 and a surface F2 opposite to the surface F1.

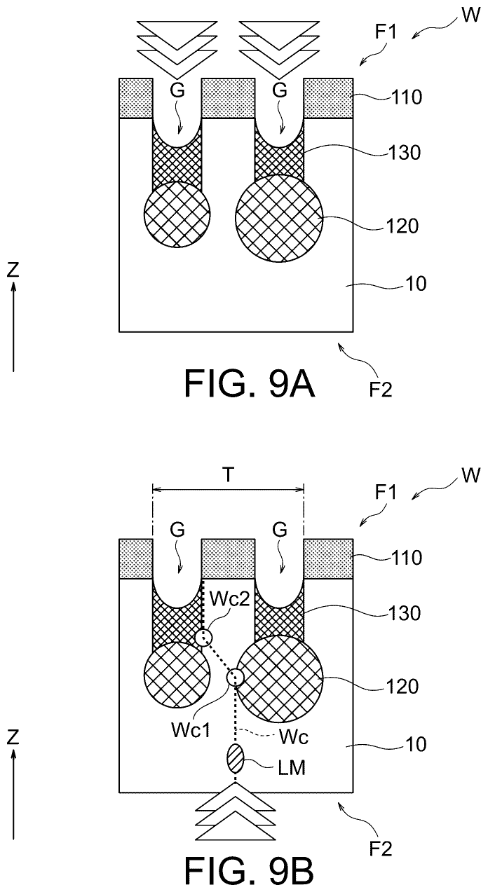

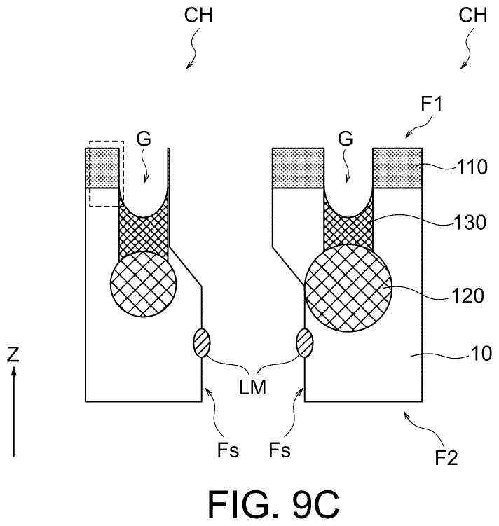

First, as illustrated in FIG. 8A, grooves (engraved portions) G are formed on the front surface (surface F1) of the semiconductor wafer W. The grooves G are formed by laser grooving, for example. Details of the grooves G will be described below with reference to FIGS. 9A to 9C.

Next, as illustrated in FIG. 8B, a protective tape is attached onto the front surface (surface F1) of the semiconductor wafer W.

Next, as illustrated in FIG. 8C, back surface grinding is lightly performed (Pre-grind) to remove a back surface film provided on the surface F2. This is because the back surface film influences on absorption efficiency during subsequent dicing using a laser beam. The process illustrated in FIG. 8C may not be necessarily performed.

Next, as illustrated in FIG. 8D, dicing is performed. In other words, a laser beam is irradiated from the surface F2 of the semiconductor wafer W to form a modified portion (modified layer) LM in the semiconductor wafer W along the dicing region Rd. A focus of the laser beam during irradiation is put between the grooves, and put in the semiconductor wafer. The modified portion LM is formed in the semiconductor substrate 10, for example. A crack Wc spreads from the modified portion LM in a direction perpendicular to the surfaces F1 and F2. The crack Wc may spread by back surface grinding which is performed later.

Next, as illustrated in FIG. 8E, back surface grinding is performed on the semiconductor wafer W. The surface F2 is ground, and the semiconductor wafer W is ground to a predetermined thickness. The back surface grinding is performed by, for example, a chemical mechanical polishing (CMP) method. The surface F2 of the semiconductor wafer W is polished until the modified portion LM is removed, for example.

Next, as illustrated in FIG. 8F, the semiconductor wafer W is mounted on a dicing tape with a ring. Then, the protective tape is removed.

Next, as illustrated in FIG. 8G, the semiconductor wafer W is segmented into a plurality of semiconductor chips CH. More specifically, the semiconductor wafer W is cleaved with the modified portion LM as a starting point to segment the semiconductor wafer W into a plurality of semiconductor chips CH. More specifically, the dicing tape having an adhesive layer, which adheres to the surface F2 of the semiconductor wafer W, is pushed up from below in FIG. 8G by a pressing member (not illustrated), thereby pulling (expanding) the dicing tape. Since each of the semiconductor chips CH are separated to cleave along the crack Wc in the dicing region Rd, the semiconductor wafer W is segmented into a plurality of semiconductor chips. As illustrated in FIG. 8H, after a segmented semiconductor chip 20 is placed on a wiring substrate 30 and then the wiring substrate 30 and the semiconductor chip 20 are electrically connected by wire bonding 15 or the like, the semiconductor chip 20 is sealed with molding resin 40.

Next, a relationship between the groove G and the crack Wc will be described.

FIGS. 9A to 9C are cross sectional views illustrating an example of the method of manufacturing the semiconductor device 100 according to the first embodiment. FIGS. 9A to 9C illustrate a part of a cross section of the dicing region Rd. Processes illustrated in FIGS. 9A to 9C correspond to the processes illustrated in FIGS. 8A, 8D, and 8G, respectively.

As illustrated in FIG. 9A, a functional film (device film) 110 is provided on the semiconductor substrate 10. The semiconductor substrate 10 is provided on the surface F2 of the semiconductor wafer W. The functional film 110 is provided on the surface F1 of the semiconductor wafer W. The functional film 110 includes a semiconductor element and an interlayer insulating film 60. The semiconductor element includes, for example, the memory cell array MCA and a control circuit.

First, as illustrated in FIG. 9A, a plurality of grooves G are formed along the inside of the dicing region Rd of the semiconductor wafer W from the surface F1 of the semiconductor wafer W. In the example illustrated in FIG. 9A, two grooves G are formed. The plurality of grooves G extend, for example, along the dicing region Rd illustrated in FIG. 1 in a direction perpendicular to the paper surface of FIG. 9A. The plurality of grooves G are arranged side by side in a left-right direction of the paper surface of FIG. 9A. In other words, the plurality of grooves G are not connected to each other and do not overlap. In the example illustrated in FIG. 9A, the grooves G reach the semiconductor substrate 10. A width of the grooves G is, for example, 10 μm, and a distance between bottoms of the grooves G is, for example, 40 μm.

The grooves G are formed by laser grooving, for example. The laser grooving is performed by laser ablation, for example. A laser beam having an ablation action has, for example, a wavelength of 600 nm or less and a pulse width of 10 nm or less.

Furthermore, when the grooves G are formed, compressive stress 120 and crystal defects 130 are generated. In other words, compressive stress and crystal defects respectively corresponding to the plurality of grooves G are formed together with the plurality of grooves G.

The compressive stress 120 and the crystal defects 130 are present near the grooves G. The crystal defect 130 is formed, for example, so as to extend downward from the groove G. The compressive stress 120 is formed, for example, below and away from the groove G, and is formed at a leading end of the crystal defect 130. The compressive stress 120 and the crystal defect 130 can be analyzed by Raman mapping, for example.

In the example illustrated in FIG. 9A, two types of compressive stress 120 have different types of magnitude. However, the compressive stress 120 may have the same magnitude.

Next, as illustrated in FIG. 9B, a laser beam is irradiated from the surface F2 of the semiconductor wafer W to form the modified portion LM in the semiconductor wafer W along the dicing region Rd. A position of the modified portion LM (a position of laser irradiation for dicing) is formed between the two grooves G when viewed in the Z direction. A plurality of modified portions LM may be formed in the Z direction. Here, “between the two grooves G” means that the modified portion LM is located in a width T between both ends of the grooves G, as illustrated in FIG. 9B. In other words, the modified portion LM may overlap one of the grooves G when viewed from above.

The laser beam having transparency used for dicing has a wavelength of 1000 nm to 1400 nm, for example. In addition, a focus is set on the dicing region Rd in the back surface grinding.

The crack Wc propagating from the modified portion LM is guided to a predetermined position in the dicing region Rd by the compressive stress 120 and the crystal defect 130.

The crack Wc propagates from the modified portion LM in a direction substantially perpendicular to the surfaces F1 and F2. The crack Wc propagates so as to avoid the compressive stress 120, and leads out upward along the brittle crystal defect 130. In the example illustrated in FIG. 9B, the course of the crack Wc is changed by the compressive stress 120 below the right groove G (Wc1 in FIG. 9B). The crack Wc approaches the compressive stress 120 at a position to the left of the center of the compressive stress 120, deviates from the compressive stress 120, and propagates toward the left groove G. Then, the crack Wc propagates in the Z direction along the crystal defect 130 of the left groove G (Wc2 in FIG. 9B). In other words, the moving line of the crack Wc is controlled by the compressive stress 120 and the crystal defect 130, and the crack Wc propagates between the two grooves G.

Next, as illustrated in FIG. 9C, the semiconductor wafer W is cleaved using the modified portion LM as a base point to segment the semiconductor wafer W into a plurality of semiconductor chips CH. The segmenting into the plurality of semiconductor chips CH is performed such that each of the semiconductor chips CH are separated to cleave along the crack Wc. The reaching point of the crack Wc on the surface F1 is located between the two grooves G. The modified portion LM appears along a side surface of the semiconductor chip CH.

The semiconductor chip CH includes the surface F1, the surface F2, and a side surface Fs. The surface F1 is a surface on which a semiconductor element is provided. The surface F2 is a surface opposite to the surface F1. The side surface Fs is a side surface between the surface F1 and the surface F2. The side surface Fs corresponds to a cut section during the segmenting.

The semiconductor chip CH includes the groove G on the front surface (surface F1) near the side surface Fs. The entire crack Wc along the dicing region Rd does not necessarily have to propagate between the two grooves G. In other words, a part of the crack Wc may propagate outside the plurality of grooves G. The groove G extends in at least a part of an outer peripheral end of the semiconductor chip CH along the outer peripheral end when viewed from the surface F1.

Furthermore, the positions of the grooves G on the surface F1 may vary depending on a distance between the two grooves G when the grooves G are formed. The wider the distance, the more likely the groove G on the surface F1 is to remain. The two grooves G may be in contact with each other when the grooves G are formed.

In the example illustrated in FIG. 9C, a cleavage is performed at a position adjacent to the groove G. However, the cleavage may be performed in the groove G. In this case, a step corresponding to the groove G is formed on the surface F1 near the side surface Fs.

Next, the functional film 110 near the groove G in FIG. 9C will be described in detail.

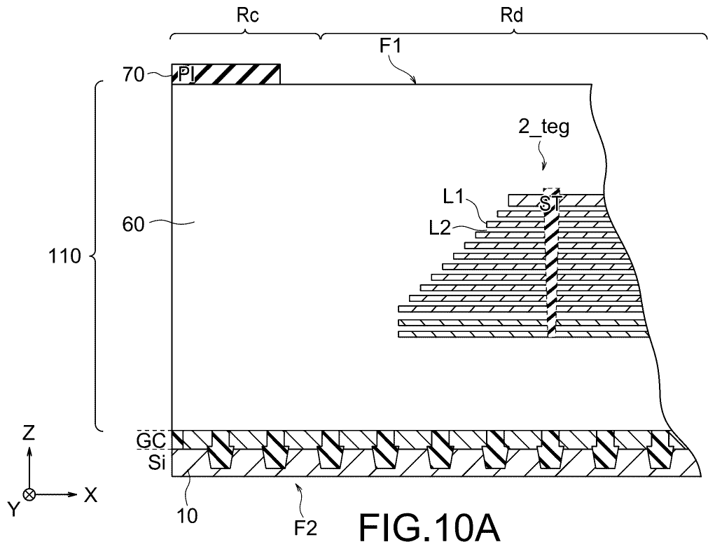

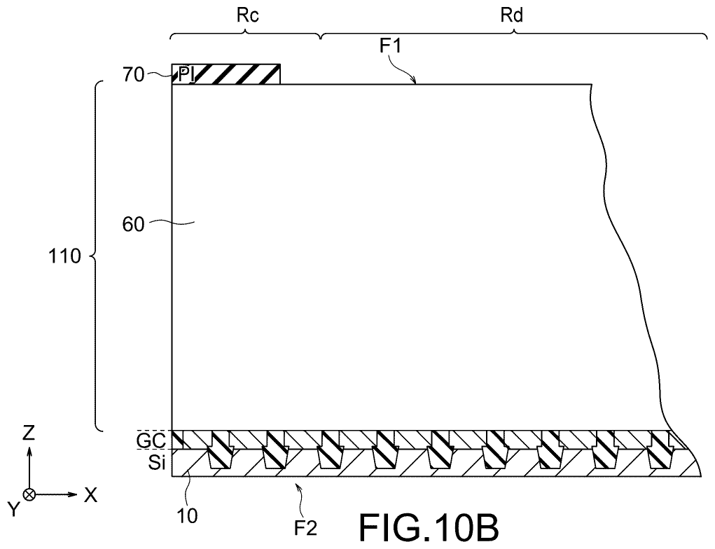

FIGS. 10A and 10B are cross sectional views illustrating an example of the configuration of the semiconductor device 100 according to the first embodiment. FIGS. 10A and 10B are enlarged cross-sectional views of a broken-line frame illustrated in FIG. 9C. FIGS. 10A and 10B illustrate cross sectional views of the functional film at different positions. FIG. 10A illustrates a cross sectional view at a position including the stacked body 2_teg. FIG. 10B illustrates a cross sectional view at a position not including the stacked body 2_teg. The stacked body 2_teg corresponds to the stacked body 2_teg illustrated in FIG. 7.

The semiconductor chip CH includes the semiconductor substrate 10, the semiconductor element, the stacked body 2_teg, the interlayer insulating film 60, and a protective film 70.

The functional film 110 includes the semiconductor element, the stacked body 2_teg, and the interlayer insulating film 60. The functional film 110 in the dicing region Rd illustrated in FIG. 10A includes the stacked body 2_teg and the interlayer insulating film 60. The functional film 110 in the dicing region Rd may further include the transistor Tr_teg illustrated in FIG. 7.

The functional film 110 has a thickness of 3 μm or more and less than 5 μm, for example. The thickness of the functional film 110 increases according to, for example, the number of stacked layers of the memory cell array MCA. The thickness of the functional film 110 may be 5 μm or more and less than 10 μm.

The semiconductor element is provided in the chip region Rc, for example. The semiconductor element is, for example, the memory cell array MCA and the control circuit. As illustrated with reference to FIGS. 2 and 7, the control circuit is arranged below the memory cell array MCA. The semiconductor element is provided in the center of the semiconductor chip CH when viewed in the direction (Z direction) substantially perpendicular to the surface F1.

The stacked body 2_teg is provided in the dicing region Rd, for example. The stacked body 2_teg is provided on the outer peripheral end of the semiconductor chip CH when viewed in the Z direction.

As illustrated in FIG. 10A, the stacked body 2_teg includes a plurality of layers L1 and a plurality of layers L2 that are alternately stacked in the Z direction. The stacked structure of the stacked body 2_teg corresponds to the stacked structure of the memory cell array MCA as described with reference to FIG. 7. For example, the layers L1 and the layers L2 of the stacked body 2_teg correspond to the conductive layer 21 and the insulating layer 22 of the memory cell array MCA, respectively. Further, the slit ST_teg illustrated in FIG. 7 is provided to penetrate the stacked body 2_teg.

In addition, a stacked body may be provided in which two types of insulators are alternately stacked, instead of the stacked body 2_teg.

The interlayer insulating film 60 is provided to cover the stacked body 2_teg. The interlayer insulating film 60 is, for example, an insulating film. The interlayer insulating film 60 is, for example, a silicon oxide film, or a stacked film including a silicon oxide film and another insulating film (for example, a silicon nitride film). The interlayer insulating film 60 is formed using, for example, tetraethoxysilane (TEOS) or the like.

The protective film 70 is provided on an upper surface of the interlayer insulating film 60. A material of the protective film 70 is, for example, polyimide (PI).

As illustrated in FIG. 10B, when the stacked body 2_teg is not provided, the interlayer insulating film 60 is provided from an upper end to a lower end of the functional film.

As described above, according to the first embodiment, the plurality of grooves G are formed to extend and be arranged side by side along the dicing region Rd of the semiconductor wafer W from the surface F1 of the semiconductor wafer W. In addition, the laser beam is irradiated between the plurality of grooves G from the surface F2 of the semiconductor wafer W to form the modified portion LM in the semiconductor wafer W along the dicing region Rd. Moreover, the semiconductor wafer W is cleaved with the modified portion LM as a starting point to segment the semiconductor wafer W into the plurality of semiconductor chips CH. Thus, the moving line of the crack Wc is controlled by the compressive stress 120 and the crystal defect 130, and the crack Wc propagates between two grooves G. As a result, the segmenting can be performed more appropriately.

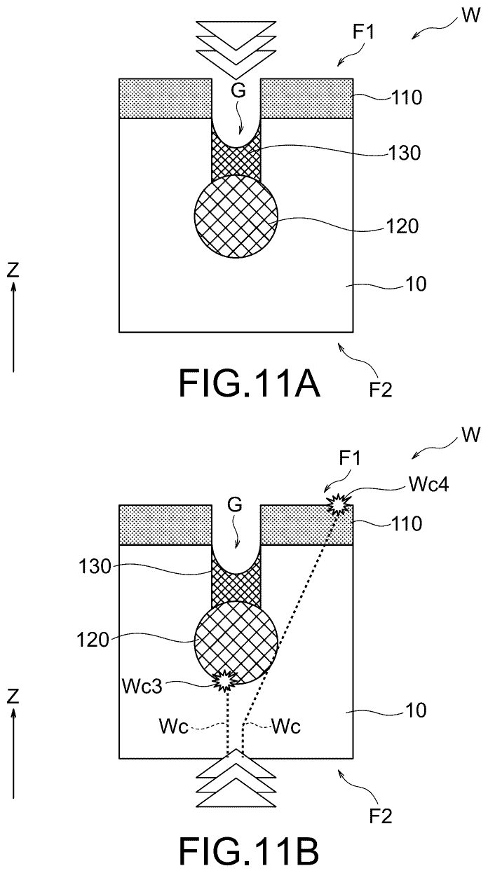

FIGS. 11A and 11B are cross sectional views illustrating an example of a method of manufacturing a semiconductor device 100 according to a comparative embodiment. The comparative embodiment differs from the first embodiment in that one groove G is formed. In FIG. 11B, the modified portion LM is omitted.

A laser beam for dicing is irradiated below the groove G. In this case, the crack Wc may be prevented from propagating from the modified portion LM due to the compressive stress 120. For example, when the crack Wc stops due to the compressive stress 120, the crack Wc does not propagate to the surface F1 and is in an unpropagated state (Wc3 in FIG. 11B). Furthermore, when the crack Wc is bent due to the compressive stress 120, the crack Wc may propagate in a meandering manner, or the crack Wc may move straight and propagate to a position away from the groove G (Wc4 in FIG. 11B). When the crack Wc moves to the position away from the groove G, this may lead to the risk of chip cracking. Furthermore, when the functional film 110 becomes complicated or thick, the laser ablation is required with high output, and the above-described defects may become more likely to occur.

In contrast, according to the first embodiment, the modified portion LM is formed between two grooves G. This makes it possible for the crack Wc to easily propagate between the two grooves G, whereby the crack Wc can be prevented from not propagating and from meandering. As a result, the segmenting can be performed more appropriately. Moreover, it is more preferable that as the functional film 110 becomes complicated or thick, the modified portion LM is formed between two grooves G.

### Second Embodiment

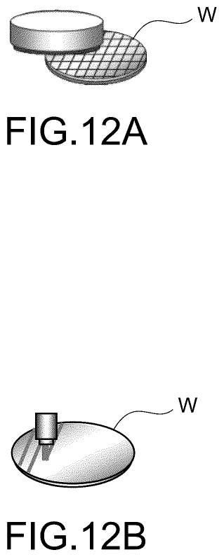

FIGS. 12A and 12B are perspective views illustrating an example of a method of manufacturing a semiconductor device 100 according to a second embodiment. The second embodiment differs from the first embodiment in that dicing is performed after back surface grinding. Processes illustrated in FIGS. 12A and 12B are performed after the process illustrated in FIG. 8B.

After a protective tape is attached onto the front surface (surface F1) of the semiconductor wafer W (see FIG. 8B), back surface grinding is performed on the semiconductor wafer W, as illustrated in FIG. 12A.

Next, dicing is performed as illustrated in FIG. 12B.

Thereafter, processes similar to those in FIGS. 8F and 8G are performed.

As described in the second embodiment, the dicing may be performed after the back surface grinding. In this case, the same effects as in the first embodiment can also be obtained.

### Third Embodiment

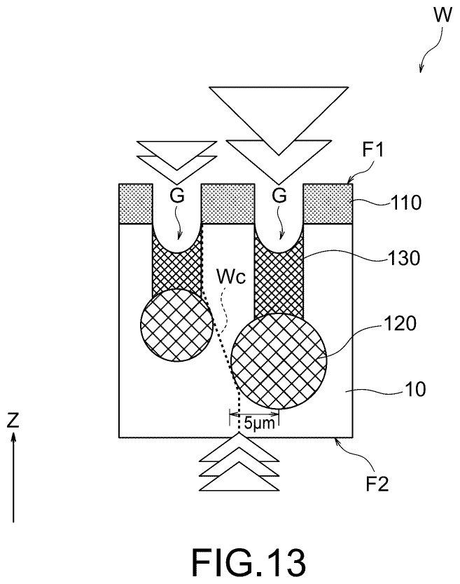

FIG. 13 is a cross sectional view illustrating an example of a method of manufacturing a semiconductor device 100 according to a third embodiment. The third embodiment differs from the first embodiment in that the laser ablation is performed with high output.

In FIG. 13, the modified portion LM is omitted.

The crack Wc propagating from the modified portion LM is guided according to formation conditions of the grooves G. The formation conditions of the grooves G include, for example, at least one of the positions and number of grooves G on the dicing region Rd, and irradiation conditions of the laser beam for forming the grooves G. The irradiation conditions include, for example, at least one of the output of the laser ablation and the number of paths.

The magnitude of the compressive stress 120 and the depth of the crystal defect 130 can be controlled by the output of the laser ablation, an irradiation pitch, the number of paths, or a focal position. Therefore, the moving line of the crack Wc can be controlled by the output of the laser ablation, the irradiation pitch, the number of paths, or the focal position.

In the example illustrated in FIG. 13, the output during formation of a right groove G is larger than the output during formation of a left groove G. This allows the compressive stress 120 of the right groove G to be larger than the compressive stress 120 of the left groove G. Furthermore, the crystal defect 130 of the right groove G is deeper than the crystal defect 130 of the left groove G. As a result, bendability of the crack Wc can be improved. The compressive stress 120 and the crystal defect 130 may also change depending on the irradiation pitch, the number of paths, or the focal position. The focal point of the laser irradiated from the surface F2 is preferably aimed at a range of about 5 μm away from the center of the region where the compressive stress 120 is formed toward the adjacent groove.

As described in the third embodiment, the laser ablation may be performed with high output. In this case, the same effects as in the first embodiment can also be obtained. In addition, the compressive stress 120 and the crystal defect 130 may also change depending on the irradiation pitch, the number of paths, or the focal position.

### Fourth Embodiment

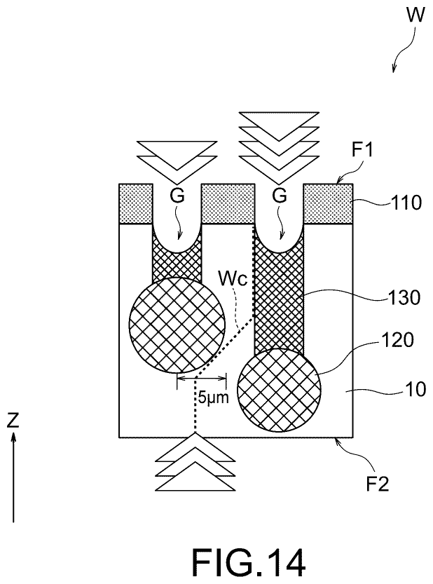

FIG. 14 is a cross sectional view illustrating an example of a method of manufacturing a semiconductor device 100 according to a fourth embodiment. The fourth embodiment differs from the first embodiment in that the laser ablation are performed with multiple paths at the same location.

The depth of the crystal defect 130 can be controlled by the output of laser ablation, the irradiation pitch, the number of paths, or the focal position. Therefore, the moving line of the crack Wc can be controlled by the output of laser ablation, the irradiation pitch, the number of paths, or the focal position.

In the example illustrated in FIG. 14, the number of paths during formation of a right groove G is larger than the number of paths during formation of a left groove G. This allows the crystal defect 130 of the right groove G to be deeper than the crystal defect 130 of the left groove G. As a result, the meandering of the crack Wc can be further prevented. In addition, the crystal defect 130 may also change depending on the output, the irradiation pitch, or the focal position.

As described in the fourth embodiment, the laser ablation may be performed with multiple paths at the same location. In this case, the same effects as in the first embodiment can also be obtained. The crystal defect 130 may also change depending on the output, the irradiation pitch, or the focal position.

### Fifth Embodiment

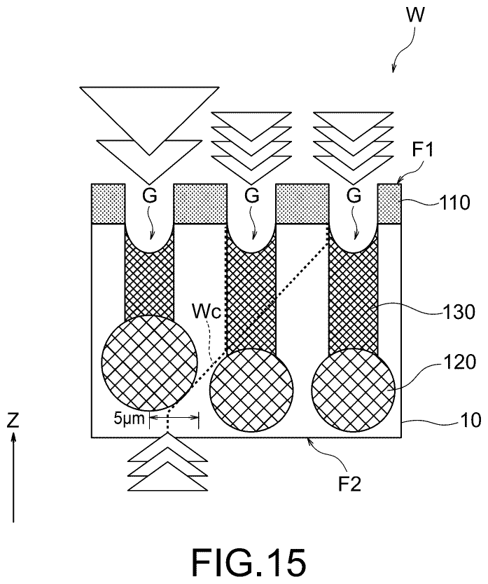

FIG. 15 is a cross sectional view illustrating an example of a method of manufacturing a semiconductor device 100 according to a fifth embodiment. The fifth embodiment differs from the first embodiment in that three grooves G are formed.

In the example illustrated in FIG. 15, three grooves G are formed. The laser ablation is performed on some of the grooves G with high output and multiple paths as described in the third and fourth embodiments.

The modified portion LM is located between a left groove G and a central groove G. The crack Wc leads out to the surface F1 along the crystal defect 130 in a right groove G even when passing through the crystal defect 130 in the central groove G. Therefore, it is possible to easily stop propagation of the crack Wc in the left-right direction of the paper surface in FIG. 15 by increasing the number of grooves G. This makes it possible to further prevent the meandering of the crack Wc. As a result, it is possible to easily guide the crack Wc.

Moreover, the modified portion LM may be located between the left groove G and the right groove G. In other words, a region between the grooves G, which are located at both outer ends, out of the three grooves G (plurality of grooves G) is irradiated with the laser beam in dicing.

Furthermore, depending on the propagating position of the crack Wc, the segmented semiconductor chip CH may include a plurality of grooves G extending along the outer peripheral end and arranged side by side.

As described in the fifth embodiment, three grooves G may be formed. In this case, the same effects as in the first embodiment can also be obtained.

### Sixth Embodiment

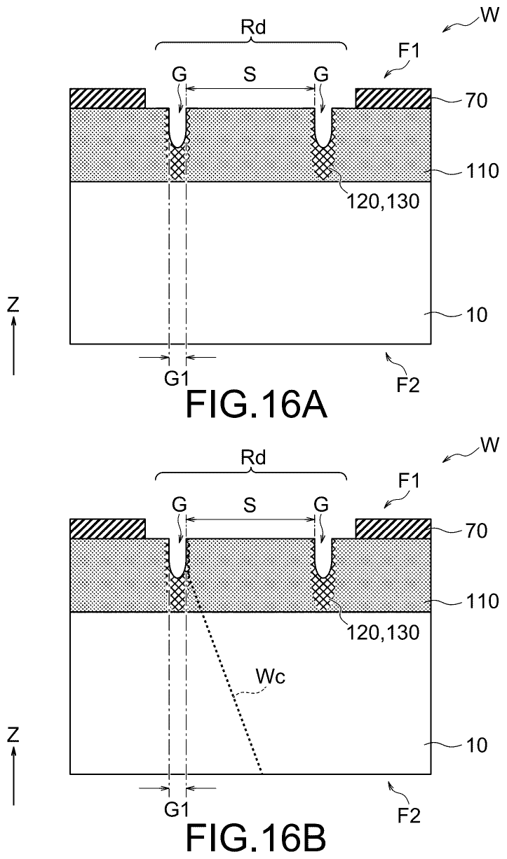

FIGS. 16A and 16B are cross sectional views illustrating an example of a method of manufacturing a semiconductor device 100 according to a sixth embodiment. The sixth embodiment differs from the first embodiment in that depths of two grooves G reach the inside of the functional film 110. Processes illustrated in FIGS. 16A and 16B correspond to the processes illustrated in FIGS. 9A and 9B according to the first embodiment.

FIGS. 16A and 16B illustrate collectively the compressive stress 120 and the crystal defect 130.

Two grooves G are provided. The two grooves G are formed from the surface F1 to the inside of the functional film 110. In other words, the two grooves G have a depth not reaching from the surface F1 to the semiconductor substrate 10.

Even when the propagating direction of the Crack Wc deviates from the center of the dicing region Rd, the compressive stress 120 or the crystal defect 130 formed by the groove G or laser ablation can prevent the crack Wc from deviating outside the compressive stress 120 or the crystal defect 130.

Furthermore, the two grooves G have the same depth. The crystal defect 130 and the compressive stress 120 have the same position and magnitude in the Z direction between the two grooves G. In other words, the two grooves G are formed under the same conditions. However, the two grooves G may be formed under different conditions. A width G1 of the groove G is smaller than a distance between the grooves. In other words, a width of a flat portion S, which is a portion formed including no groove between the grooves G, is larger than the width G1 of the groove G.

As described in the sixth embodiment, the depths of the two grooves G may reach the inside of the functional film 110. In this case, the same effects as in the first embodiment can also be obtained.

### Seventh Embodiment

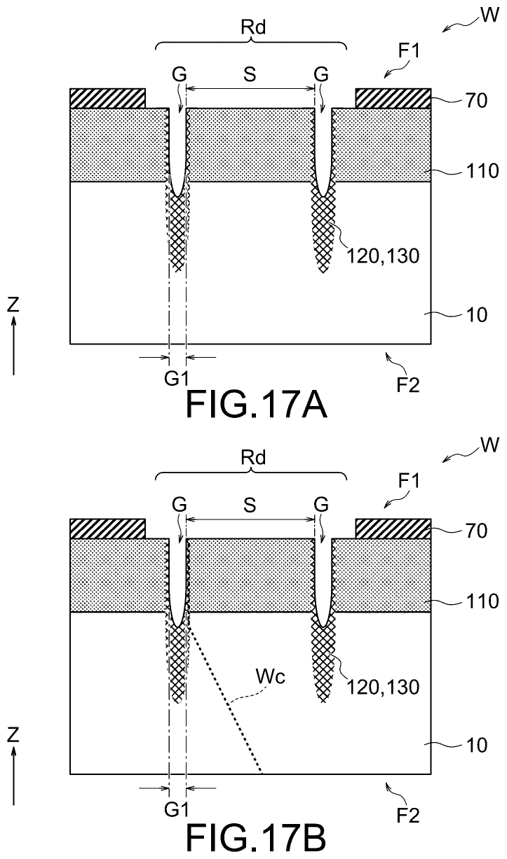

an FIGS. 17A and 17B are cross sectional views illustrating example of a method of manufacturing a semiconductor device 100 according to a seventh embodiment. The seventh embodiment differs from the sixth embodiment in that a plurality of grooves G reach the semiconductor substrate 10.

The two grooves G have a depth that penetrates the functional film 110 from the surface F1 and reaches the semiconductor substrate 10.

As the groove G becomes deeper, the meandering of the crack Wc can be prevented more easily. As the groove G becomes deeper, it may be more difficult to engrave the groove G, and it may take a time to engrave. On the other hand, as the groove G becomes shallower, the compressive stress 120 becomes smaller, whereby the meandering of the crack Wc may be also difficult to occur. The depth of the groove G may be set according to circumstances such as easiness of the meandering of the actual crack Wc.

Furthermore, the two grooves G have the same depth. The crystal defect 130 and the compressive stress 120 have the same position and magnitude in the Z direction between the two grooves G. In other words, the two grooves G are formed under the same conditions. However, the two grooves G may be formed under different conditions.

As described in the seventh embodiment, the plurality of grooves G may reach the semiconductor substrate 10. In this case, the same effects as in the sixth embodiment can also be obtained.

### Eighth Embodiment

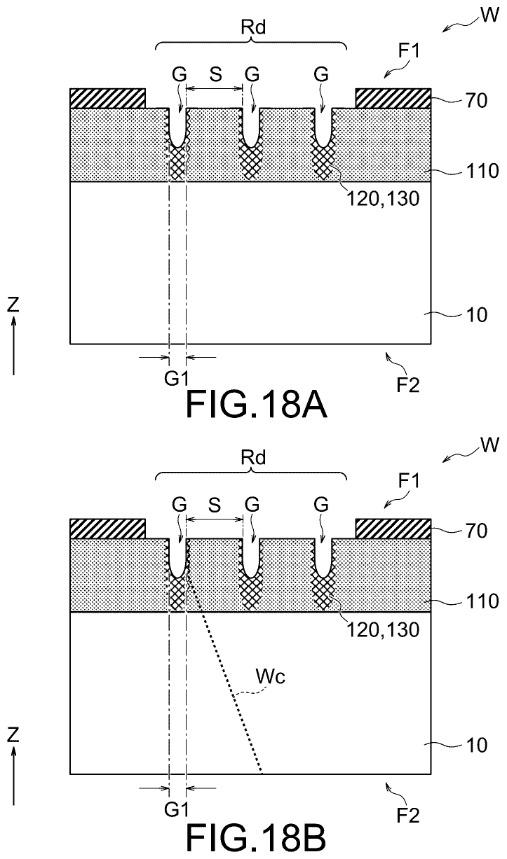

FIGS. 18A and 18B are cross sectional views illustrating an example of a method of manufacturing a semiconductor device 100 according to an eighth embodiment. The eighth embodiment differs from the sixth embodiment in that three grooves G are formed.

Three grooves G are provided. The three grooves G are formed from the surface F1 to the inside of the functional film 110. In other words, the three grooves G have a depth not reaching the semiconductor substrate 10. A width G1 of the groove G is smaller than a distance between the grooves. In other words, a width of a flat portion S, which is a portion formed including no groove between the grooves G, is larger than the width G1 of the groove G.

Similarly to the fifth embodiment described with reference to FIG. 15, as the number of grooves G becomes greater, the meandering of the crack Wc can be further prevented. As a result, it is possible to easily guide the crack Wc.

As described in the eighth embodiment, the three grooves G may be formed. In this case, the same effects as in the sixth embodiment can also be obtained. In the case where the three grooves G are formed in this manner, when the chips are segmented, two grooves G may remain in one of two adjacent chips. When a plurality of grooves remain, adhesion with molding resin at the end of the chip increases.

### Ninth Embodiment

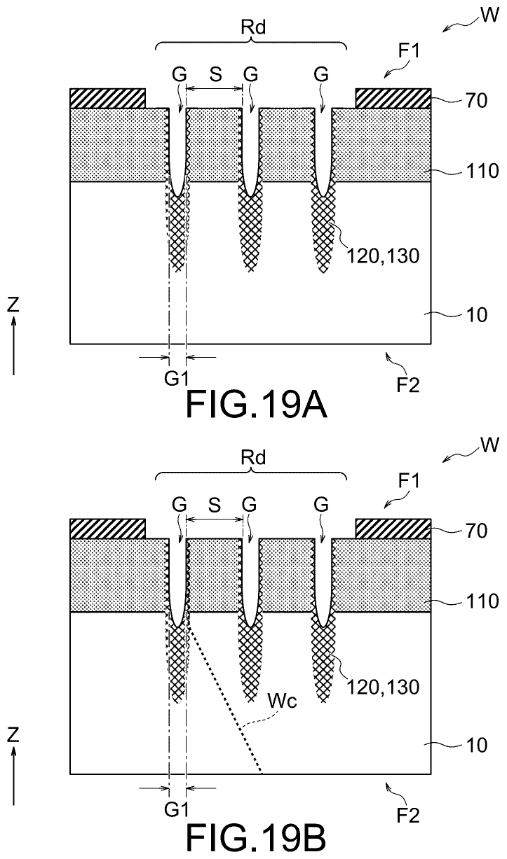

FIGS. 19A and 19B are cross sectional views illustrating an example of a method of manufacturing a semiconductor device 100 according to a ninth embodiment. The ninth embodiment differs from the eighth embodiment in that three grooves G reach the semiconductor substrate 10. In other words, the ninth embodiment is a combination of the seventh embodiment and the eighth embodiment.

The three grooves G have a depth that penetrates the functional film 110 and reaches the semiconductor substrate 10.

As described in the ninth embodiment, the three grooves G may reach the semiconductor substrate 10. In this case, the same effects as in the eighth embodiment can also be obtained.

### Tenth Embodiment

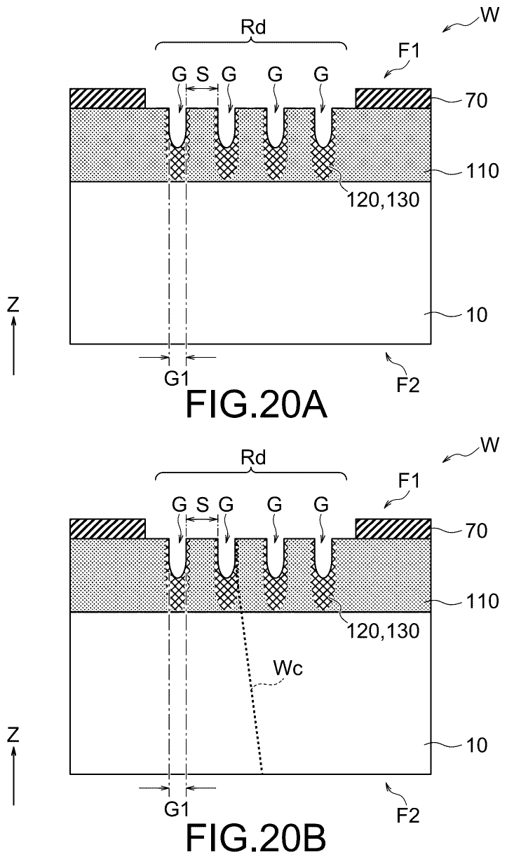

FIGS. 20A and 20B are cross sectional views illustrating an example of a method of manufacturing a semiconductor device 100 according to a tenth embodiment. The tenth embodiment differs from the sixth embodiment in that four grooves G are formed.

Four grooves G are provided. The four grooves G are formed from the surface F1 to the inside of the functional film 110. In other words, the four grooves G have a depth not reaching the semiconductor substrate 10. A width G1 of the groove G is smaller than a distance between the grooves. In other words, a width of a flat portion S, which is a portion formed including no groove between the grooves G, is larger than the width G1 of the groove G.

As described in the tenth embodiment, the four grooves G may be formed. In this case, the same effects as in the sixth embodiment can also be obtained. In the case where the four grooves G are formed in this manner, when the chips are segmented, two or three grooves G may remain in one of two adjacent chips. When a plurality of grooves remain, adhesion with molding resin at the end of the chip increases.

### Eleventh Embodiment

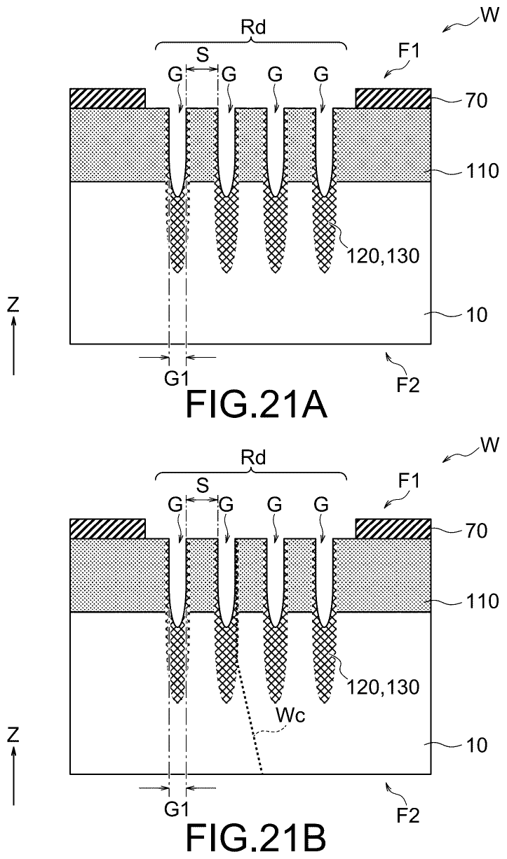

FIGS. 21A and 21B are cross sectional views illustrating an example of a method of manufacturing a semiconductor device 100 according to an eleventh embodiment. The eleventh embodiment differs from the eighth embodiment in that four grooves G reach the semiconductor substrate 10. In other words, the eleventh embodiment is a combination of the seventh embodiment and the tenth embodiment.

The four grooves G have a depth that penetrates the functional film 110 and reaches the semiconductor substrate 10.

As described in the eleventh embodiment, the four grooves G may reach the semiconductor substrate 10. In this case, the same effects as in the tenth embodiment can also be obtained.

### Twelfth Embodiment

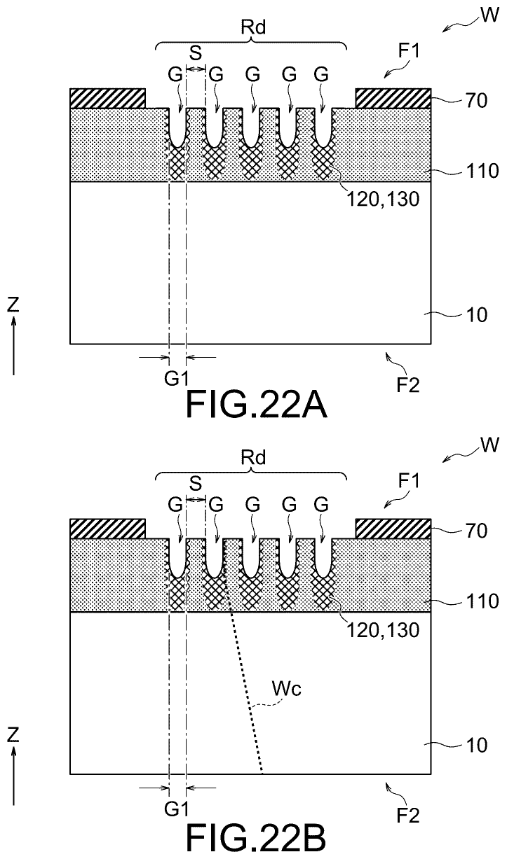

FIGS. 22A and 22B are cross sectional views illustrating an example of a method of manufacturing a semiconductor device 100 according to a twelfth embodiment. The twelfth embodiment differs from the sixth embodiment in that five grooves G are formed.

Five grooves G are provided. The five grooves G are formed from the surface F1 to the inside of the functional film 110. In other words, the five grooves G have a depth not reaching the semiconductor substrate 10. A width G1 of the groove G is smaller than a distance between the grooves. In other words, a width of a flat portion S, which is a portion formed including no groove between the grooves G, is larger than the width G1 of the groove G.

As described in the twelfth embodiment, the five grooves G may be formed. In this case, the same effects as in the sixth embodiment can also be obtained. In the case where the five grooves G are formed in this manner, when the chips are segmented, two to four grooves G may remain in one of two adjacent chips. When a plurality of grooves remain, adhesion with molding resin at the end of the chip increases.

### Thirteenth Embodiment

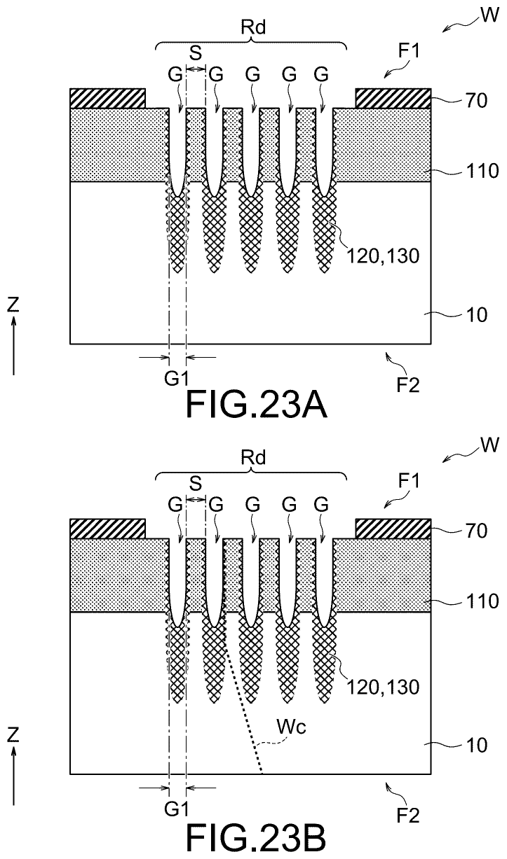

FIGS. 23A and 23B are cross sectional views illustrating an example of a method of manufacturing a semiconductor device 100 according to a thirteenth embodiment. The thirteenth embodiment differs from the twelfth embodiment in that five grooves G reach the semiconductor substrate 10. In other words, the thirteenth embodiment is a combination of the seventh embodiment and the twelfth embodiment.

The five grooves G have a depth that penetrates the functional film 110 and reaches the semiconductor substrate 10.

As described in the thirteenth embodiment, the five grooves G may reach the semiconductor substrate 10. In this case, the same effects as in the twelfth embodiment can also be obtained.

### Fourteenth Embodiment

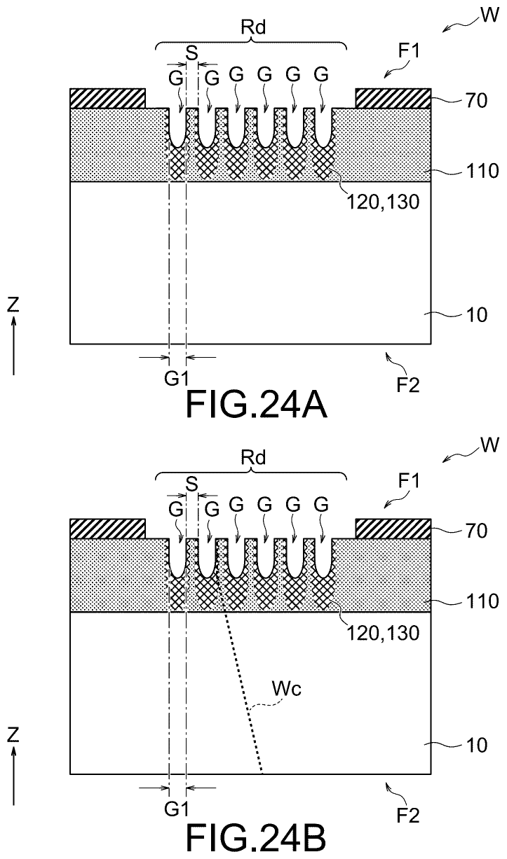

FIGS. 24A and 24B are cross sectional views illustrating an example of a method of manufacturing a semiconductor device 100 according to a fourteenth embodiment. The fourteenth embodiment differs from the sixth embodiment in that six grooves G are formed.

Six grooves G are provided. The six grooves G are formed from the surface F1 to the inside of the functional film 110. In other words, the six grooves G have a depth not reaching the semiconductor substrate 10. A width G1 of the groove G is larger than a distance between the grooves. In other words, a width of a flat portion S, which is a portion formed including no groove between the grooves G, is smaller than the width G1 of the groove G.

As described in the fourteenth embodiment, the six grooves G may be formed. In this case, the same effects as in the sixth embodiment can also be obtained. In the case where the six grooves G are formed in this manner, when the chips are segmented, two to five grooves G may remain in one of two adjacent chips. When a plurality of grooves remain, adhesion with molding resin at the end of the chip increases.

### Fifteenth Embodiment

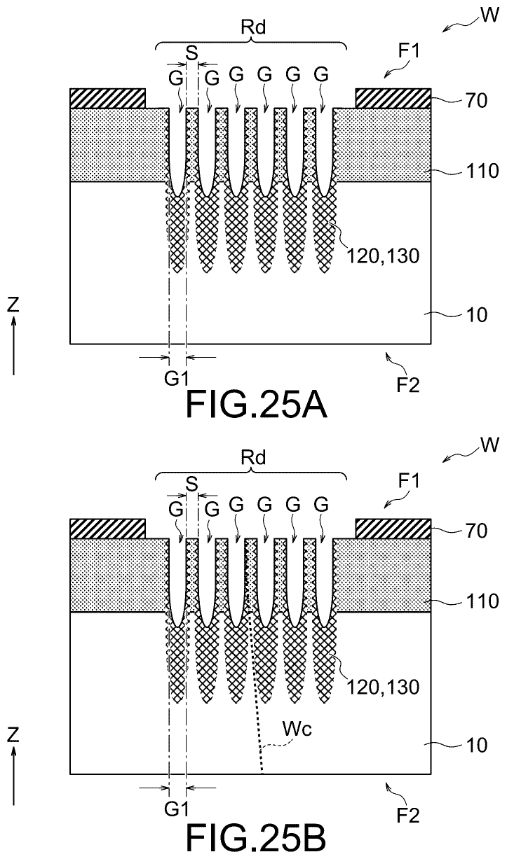

FIGS. 25A and 25B are cross sectional views illustrating an example of a method of manufacturing a semiconductor device 100 according to a fifteenth embodiment. The fifteenth embodiment differs from the fourteenth embodiment in that six grooves G reach the semiconductor substrate 10. In other words, the fifteenth embodiment is a combination of the seventh embodiment and the fourteenth embodiment.

The six grooves G have a depth that penetrates the functional film 110 and reaches the semiconductor substrate 10.

As described in the fifteenth embodiment, the six grooves G may reach the semiconductor substrate 10. In this case, the same effects as in the fourteenth embodiment can also be obtained.

### Sixteenth Embodiment

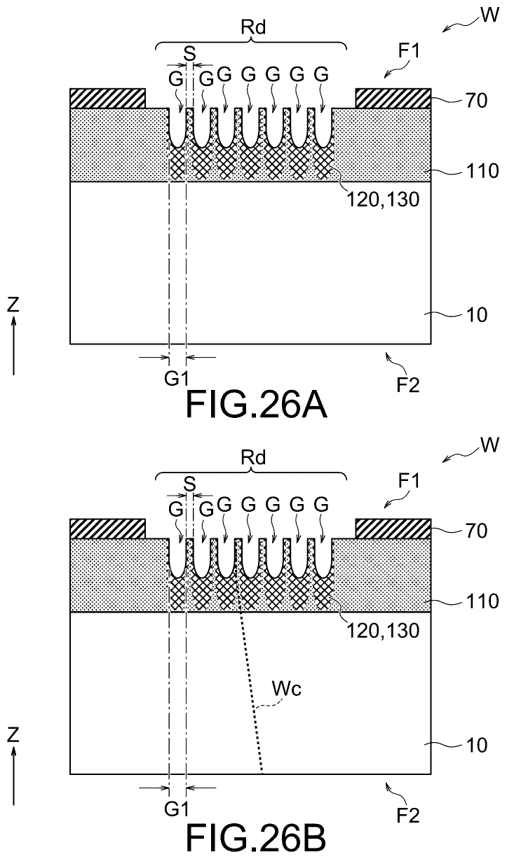

FIGS. 26A and 26B are cross sectional views illustrating an example of a method of manufacturing a semiconductor device 100 according to a sixteenth embodiment. The sixteenth embodiment differs from the sixth embodiment in that seven grooves G are formed.

Seven grooves G are provided. The seven grooves G are formed from the surface F1 to the inside of the functional film 110. In other words, the seven grooves G have a depth not reaching the semiconductor substrate 10. A width G1 of the groove G is larger than a distance between the grooves. In other words, a width of a flat portion S, which is a portion formed including no groove between the grooves G, is smaller than the width G1 of the groove G.

As described in the sixteenth embodiment, the seven grooves G may be formed. In this case, the same effects as in the sixth embodiment can also be obtained. In the case where the seven grooves G are formed in this manner, when the chips are segmented, two to six grooves G may remain in one of two adjacent chips. When a plurality of grooves remain, adhesion with molding resin at the end of the chip increases.

### Seventeenth Embodiment

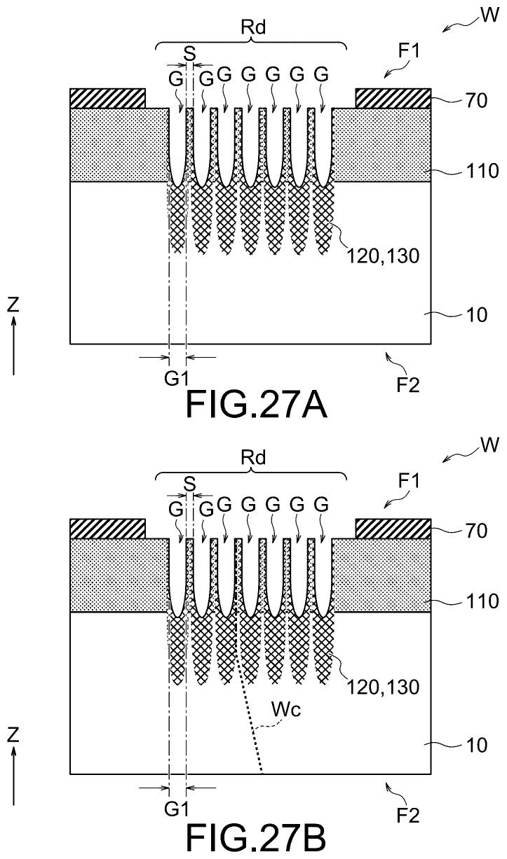

FIGS. 27A and 27B are cross sectional views illustrating an example of a method of manufacturing a semiconductor device 100 according to a seventeenth embodiment. The seventeenth embodiment differs from the sixteenth embodiment in that seven grooves G reach the semiconductor substrate 10. In other words, the seventeenth embodiment is a combination of the seventh embodiment and the sixteenth embodiment.

The seven grooves G have a depth that penetrates the functional film 110 and reaches the semiconductor substrate 10.

In addition, eight or more grooves G may be provided.

As described in the seventeenth embodiment, the seven grooves G may reach the semiconductor substrate 10. In this case, the same effects as in the sixteenth embodiment can also be obtained.

As the width of the flat portion S becomes smaller, the crack Wc is easily guided. However, when the number of grooves G is small, the focus of the laser in the XY direction irradiated from the surface F2 is likely to deviate from the space between the grooves G. When the number of grooves G is large, the focus of the laser is less likely to deviate, but the grooves G need to be processed several times. As the width of the flat portion S becomes larger, the crack Wc is more likely to meander between the flat portions S. However, even when the number of grooves G is small, the focus of the laser in the XY direction irradiated from the surface F2 is less likely to deviate from the space between the grooves G. The relationship between the number of grooves G and the flat portion S is adjusted as appropriate. For example, when the number of grooves G is 2 to 4, the width G1 of the groove may be narrower than the width of the flat portion S. For example, when the number of grooves G is five or move, the width G1 of the groove may be larger than the width of the flat portion S.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A method of manufacturing a semiconductor device, comprising:
forming two grooves that extend from a first surface of a semiconductor wafer along a dicing region of the semiconductor wafer and are arranged side by side, the semiconductor wafer including the first surface and a second surface opposite to the first surface;
irradiating between the two grooves from the second surface of the semiconductor wafer with a first laser beam when viewed from above to form a modified portion in the semiconductor wafer along the dicing region; and
cleaving the semiconductor wafer to segment the semiconductor wafer into a plurality of semiconductor chips.

2. The method of manufacturing a semiconductor device of claim 1, wherein
the cleaving the semiconductor wafer includes
cleaving the semiconductor wafer with the modified portion as a starting point.

3. The method of manufacturing a semiconductor device of claim 1, wherein
the forming the two grooves includes forming a region in which compressive stress occurs and a crystal defect which correspond to each of the two grooves.

4. The method of manufacturing a semiconductor device of claim 1, further comprising:
forming at least one more grooves from the first surface of the semiconductor wafer to form at least three or more grooves extending along the dicing region of the semiconductor wafer, wherein
the irradiating between the two grooves with the first laser beam is irradiating a region between the grooves, which are located at both outer ends, out of the at least three or more grooves with the first laser beam.

5. The method of manufacturing a semiconductor device of claim 1, wherein
a width of a portion formed between the two grooves is smaller than a width of each of the grooves.

6. The method of manufacturing a semiconductor device of claim 1, wherein
a width of a portion formed between the two grooves is larger than a width of each of the grooves.

7. The method of manufacturing a semiconductor device of claim 1, wherein
the semiconductor wafer includes
a semiconductor substrate including the second surface, and
a film including the first surface and a semiconductor element, and
the two grooves penetrate the film from the first surface and are formed to a depth that reaches the semiconductor substrate.

8. The method of manufacturing a semiconductor device of claim 1, wherein
the semiconductor wafer includes
a semiconductor substrate including the second surface, and
a film including the first surface and a semiconductor element, and
the two grooves are formed from the first surface to a depth that does not reach the semiconductor substrate.

9. The method of manufacturing a semiconductor device of claim 7, wherein
the film has a thickness of 5 μm or more and less than 10 μm.

10. The method of manufacturing a semiconductor device of claim 1, wherein
the two grooves are formed by laser ablation using a second laser beam.

11. The method of manufacturing a semiconductor device of claim 10, wherein
the first laser beam has a wavelength of 1000 nm to 1400 nm, and
the second laser beam has a wavelength of 600 nm or less and a pulse width of 10 nm or less.

12. The method of manufacturing a semiconductor device of claim 8, wherein
the film has a thickness of 5 μm or more and less than 10 μm.

13. A semiconductor device comprising a first surface and a second surface opposite to the first surface,
the semiconductor device further comprising:
a semiconductor element that is provided at a center of the semiconductor device when viewed from a direction substantially perpendicular to the first surface;
at least two grooves that, in at least a part of an outer peripheral end of the semiconductor device when viewed from the direction substantially perpendicular to the first surface, extend along the outer peripheral end; and
a modified portion that is formed on a side surface of the semiconductor device.

14. The semiconductor device of claim 13, further comprising
a region in which compressive stress occurs and a crystal defect that correspond to each of the at least two grooves.

15. The semiconductor device of claim 13, wherein
the semiconductor device includes
a semiconductor substrate including the second surface, and
a film including the first surface and a semiconductor element, and
the at least two grooves have a depth that does not reach the semiconductor substrate.

16. The semiconductor device of claim 13, wherein
the semiconductor device includes
a semiconductor substrate including the second surface, and
a film including the first surface and a semiconductor element, and
the at least two grooves have a depth that reaches the semiconductor substrate.

17. The semiconductor device of claim 12, wherein
a width of a portion formed between the two grooves is smaller than a width of each of the grooves.

18. The semiconductor device of claim 12, wherein
a width of a portion formed between the two grooves is larger than a width of each of the grooves.
